(19) United States
(12) Patent Application Publication
(10) Pub. No.: US 2014/0115886 A1
(43) Pub. Date: May 1, 2014

(54) METHOD AND SYSTEM FOR MARKING SUBSTRATE AND PLACING COMPONENTS FOR HIGH ACCURACY

(71) Applicants: VOLEX PLC, LONDON (GB); APPLIED MICRO CIRCUITS CORPORATION, SUNNYVALE, CA (US)

(72) Inventor: Benoit SEVIGNY, Mountain View, CA (US)

(73) Assignees: VOLEX PLC, LONDON (GB); APPLIED MICRO CIRCUITS CORPORATION, SUNNYVALE, CA (US)

(21) Appl. No.: 13/662,130

(22) Filed: Oct. 26, 2012

(51) Int. Cl. H05K 3/30; B23K 26/36

(52) U.S. Cl. CPC H05K 3/303; B23K 26/365
USPC 29/834; 29/739; 219/121.69; 219/121.68

(57) ABSTRACT

A method and system for pre-marking a substrate to provide a visual reference enabling repetitive and accurate component placement on one or more substrates. The method for marking includes determining a first location on a substrate for placing a component relative to a cut outline of the substrate. The method includes placing a fiducial at a second location on the substrate to provide a known dimensional reference to the first location, such that the fiducial and the first location are configured to be in a field-of-view of a component placement machine.

### BACKGROUND

A current method used to place component on a substrate is to reference a coordinate system with respect to a fiducial located on the board, or a fiducial located on a jig to which the board is mounted. Since a single fiducial is used as the reference for all of the components placed on the board, and the components are outside of the field of view from each other, is not possible to have the fiducial in the field of view for all of the components placed. The current method measures the location of the fiducial marks, and then translates the component placement location to the desired coordinates in order to mount the component. This introduces error from the translation of the placement machine and the number of actions required to perform the placement.

In order to achieve accuracies of a few microns, these traditional methods are extremely demanding in terms of keeping the errors between the various parts of the machine as small as possible and keeping all of those parts in reference to extremely high accuracy. This is very challenging and leads to very expensive and bulky solutions. This is especially true when relative positioning between the parts is most important, but could be extended to absolute positioning as well.

### SUMMARY

A method and system for pre-marking a substrate to provide a visual reference enabling repetitive and highly accurate component placement on one or more substrates. In one embodiment, the method for marking includes determining a first location on a substrate for placing a component relative to a cut outline of the substrate. The method includes mating the substrate to a fiducial marking system, such that a cut outline is aligned with a first reference coordinate system of the fiducial marking system. In that manner, the first location on the substrate is able to be referenced in the method using the first reference coordinate system. The method includes placing a fiducial at a second location on the substrate to provide a known dimensional reference to the first location. Placement is made using the fiducial marking system and its first coordinate system. The fiducial is placed in a manner such that the fiducial and the first location are configured to be in a field-of-view of a component placement machine.

In another embodiment, a method for pre-marking a substrate to provide a visual reference for component placement includes mating a substrate to a fiducial marking system, such that a cut outline of the substrate is aligned with a first reference coordinate system of the fiducial marking system. In one implementation, the substrate comprises printed circuits disposed on a surface of the substrate. For instance, in one implementation, the substrate comprises a printed circuit board (PCB). The method includes determining a first location on the substrate for placing a component relative to the cut outline of the substrate. The method also includes placing a fiducial at the first location on the substrate. In that manner, a component can be placed by a component placement machine at the location marked by the fiducial without consideration of a reference coordinate system.

In still another embodiment, an apparatus the is configured for pre-marking a substrate to provide a visual reference for component placement is disclosed. The apparatus includes a substrate. In one embodiment, the substrate comprises a circuit pattern disposed on a surface of the substrate. The apparatus includes a first location on the substrate, wherein the first location indicates where a component is to be placed on the substrate relative to a cut outline of the substrate. The apparatus includes a fiducial marking a second location on the substrate. The fiducial provides a known dimensional reference to the first location. The fiducial and the first location are configured such that they are both within a field-of-view of a component placement machine, thereby providing highly accurate placement of a component at the first location on the substrate.

### BRIEF DESCRIPTION OF THE DRAWINGS

The accompanying drawings, which are incorporated in and form a part of this specification and in which like numerals depict like elements, illustrate embodiments of the present disclosure and, together with the description, serve to explain the principles of the disclosure.

FIG. 1 depicts a block diagram of an exemplary computer system suitable for implementing the present methods, in accordance with one embodiment of the present disclosure.

FIG. 2 is a diagram illustrating the process flow for pre-marking a substrate with a fiducial to provide a visual reference enabling repetitive and highly accurate component placement, and the placement of a component with reference to the fiducial, in accordance with one embodiment of the present disclosure.

FIG. 3 is a flow diagram illustrating a method for pre-marking a substrate to provide a visual reference enabling repetitive and highly accurate component placement, in accordance with one embodiment of the present disclosure.

FIG. 4A is a diagram illustrating the placement of a substrate onto a surface of fiducial marking system such that a coordinate system of the substrate is mutually aligned with a reference coordinate system of the fiducial marking system, and wherein a fiducial marks the exact location on the substrate for placing a component, in accordance with one embodiment of the present disclosure.

FIG. 4B is a diagram illustrating the placement of a substrate onto a surface of fiducial marking system such that a coordinate system of the substrate is mutually aligned with a reference coordinate system of the fiducial marking system, and wherein a fiducial marks a reference location that is offset by a known reference from the location on the substrate for placing a component, in accordance with one embodiment of the present disclosure.

FIG. 5 is a diagram illustrating the placement of a substrate onto a surface of a component placement machine, wherein the substrate is marked with a fiducial referencing the location where a component is to be placed, in accordance with one embodiment of the present disclosure.

FIG. 6 is a flow diagram illustrating a method for pre-marking a substrate with a fiducial to provide a visual reference enabling repetitive and highly accurate component placement, wherein the fiducial is placed at the exact location for component placement, in accordance with one embodiment of the present disclosure.

### DETAILED DESCRIPTION

Reference will now be made in detail to the various embodiments of the present disclosure, examples of which are illustrated in the accompanying drawings. While described in conjunction with these embodiments, it will be understood that they are not intended to limit the disclosure to these embodiments. On the contrary, the disclosure is intended to cover alternatives, modifications and equivalents, which may be included within the spirit and scope of the disclosure as defined by the appended claims. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure.

Some portions of the detailed descriptions that follow are presented in terms of procedures, logic blocks, processing, and other symbolic representations of operations on data bits within a computer memory. These descriptions and representations are the means used by those skilled in the data processing arts to most effectively convey the substance of their work to others skilled in the art. In the present application, a procedure, logic block, process, or the like, is conceived to be a self-consistent sequence of steps or instructions leading to a desired result. The steps are those utilizing physical manipulations of physical quantities. Usually, although not necessarily, these quantities take the form of electrical or magnetic signals capable of being stored, transferred, combined, compared, and otherwise manipulated in a computer system. It has proven convenient at times, principally for reasons of common usage, to refer to these signals as transactions, bits, values, elements, symbols, characters, samples, pixels, or the like.

It should be borne in mind, however, that all of these and similar terms are to be associated with the appropriate physical quantities and are merely convenient labels applied to these quantities. Unless specifically stated otherwise as apparent from the following discussions, it is appreciated that throughout the present disclosure, discussions utilizing terms such as “configuring,” “placing,” “marking,” or the like, refer to actions and processes of a computer system or similar electronic computing device or processor. The computer system or similar electronic computing device manipulates and transforms data represented as physical (electronic) quantities within the computer system memories, registers or other such information storage, transmission or display devices.

Flowcharts are provided of examples of computer-implemented methods for processing data according to embodiments of the present invention. Although specific steps are disclosed in the flowcharts, such steps are exemplary. That is, embodiments of the present invention are well-suited to performing various other steps or variations of the steps recited in the flowcharts.

Embodiments of the present invention described herein are discussed within the context of hardware-based components configured for monitoring and executing instructions. That is, embodiments of the present invention are implemented within hardware devices of a micro-architecture, and are configured for monitoring for critical stall conditions and performing appropriate clock-gating for purposes of power management.

Other embodiments described herein may be discussed in the general context of computer-executable instructions residing on some form of computer-readable storage medium, such as program modules, executed by one or more computers or other devices. By way of example, and not limitation, computer-readable storage media may comprise non-transitory computer storage media and communication media. Generally, program modules include routines, programs, objects, components, data structures, etc., that perform particular tasks or implement particular abstract data types. The functionality of the program modules may be combined or distributed as desired in various embodiments.

Computer storage media includes volatile and nonvolatile, removable and non-removable media implemented in any method or technology for storage of information such as computer-readable instructions, data structures, program modules or other data. Computer storage media includes, but is not limited to, random access memory (RAM), read only memory (ROM), electrically erasable programmable ROM (EEPROM), flash memory or other memory technology, compact disk ROM (CD-ROM), digital versatile disks (DVDs) or other optical storage, magnetic cassettes, magnetic tape, magnetic disk storage or other magnetic storage devices, or any other medium that can be used to store the desired information and that can accessed to retrieve that information.

Communication media can embody computer-executable instructions, data structures, and program modules, and includes any information delivery media. By way of example, and not limitation, communication media includes wired media such as a wired network or direct-wired connection, and wireless media such as acoustic, radio frequency (RF), infrared and other wireless media. Combinations of any of the above can also be included within the scope of computer-readable media.

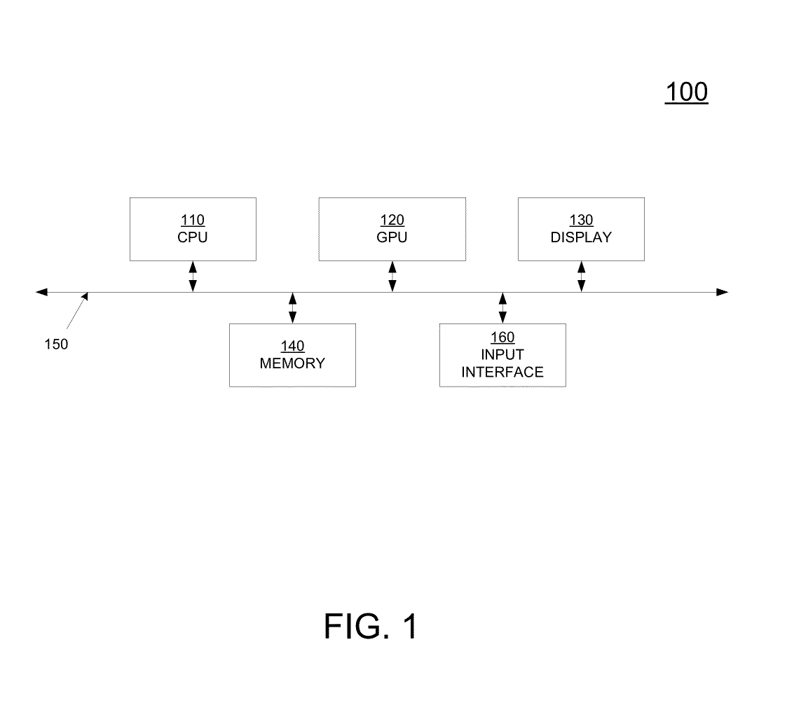

FIG. 1 is a block diagram of an example of a computing system 100 capable of implementing embodiments of the present disclosure. Computing system 10 broadly represents any single or multi-processor computing device or system capable of executing computer-readable instructions. Examples of computing system 100 include, without limitation, workstations, laptops, client-side terminals, servers, distributed computing systems, handheld devices, or any other computing system or device. In its most basic configuration, computing system 100 may include at least one processor 110 and a system memory 140.

Both the central processing unit (CPU) 110 and the graphics processing unit (GPU) 120 are coupled to memory 140. System memory 140 generally represents any type or form of volatile or non-volatile storage device or medium capable of storing data and/or other computer-readable instructions. Examples of system memory 140 include, without limitation, RAM, ROM, flash memory, or any other suitable memory device. In the example of FIG. 1, memory 140 is a shared memory, whereby the memory stores instructions and data for both the CPU 110 and the GPU 120. Alternatively, there may be separate memories dedicated to the CPU 110 and the GPU 120, respectively. The memory can include a frame buffer for storing pixel data drives a display screen 130.

The system 100 includes a user interface 160 that, in one implementation, includes an on-screen cursor control device. The user interface may include a keyboard, a mouse, and/or a touch screen device (a touchpad).

CPU 110 and/or GPU 120 generally represent any type or form of processing unit capable of processing data or interpreting and executing instructions. In certain embodiments, processors 110 and/or 120 may receive instructions from a software application or hardware module. These instructions may cause processors 110 and/or 120 to perform the functions of one or more of the example embodiments described and/or illustrated herein. For example, processors 110 and/or 120 may perform and/or be a means for performing, either alone or in combination with other elements, one or more of the monitoring, determining, gating, and detecting, or the like described herein. Processors 110 and/or 120 may also perform and/or be a means for performing any other steps, methods, or processes described and/or illustrated herein.

In some embodiments, the computer-readable medium containing a computer program may be loaded into computing system 100. All or a portion of the computer program stored on the computer-readable medium may then be stored in system memory 140 and/or various portions of storage devices. When executed by processors 110 and/or 120, a computer program loaded into computing system 100 may cause processor 110 and/or 120 to perform and/or be a means for performing the functions of the example embodiments described and/or illustrated herein. Additionally or alternatively, the example embodiments described and/or illustrated herein may be implemented in firmware and/or hardware.

Accordingly, embodiments of the present disclosure provide for pre-marking of a substrate to provide a visual reference allowing accurate component placement on the substrate. The process is repeatable on one or more substrates thereby allowing repetitive and accurate component placement on multiple substrates.

Throughout this application various terms are used. The use of these terms are provided, as follows below. The term “substrate” includes a board, gold pad or other substrate on which component needs to be placed accurately, or a material added to the placement surface to enable easy marking. The term “marking laser” includes a laser used to mark the substrate. The term “components” includes optoelectronic components, or otherwise, needing to be placed accurately. The terms “fixture” or “jig” include an apparatus used to maintain the structure in place while marking. The term “algorithm” includes a method by which the shapes are recognized in order to compute the location at which components are to be placed. The term “die-attach adhesive” includes a substance used to physically bond the component to the substrate. The term “fiducial” includes a feature used to create a coordinate system on a measurement or placement device. The details of the shape of the feature, its accuracy and some requirements on its location can be a function of the machine on which they are intended to be used.

Embodiments of the present invention provide for pre-marking of a substrate to achieve high accuracy placement of components. In embodiments, a visual reference is provided that enables repetitive and accurate component placement on the substrate. Pre-marking of the substrate creates a visual reference at or near the component placement location. This reference can be used to increase placement accuracy by reducing or eliminating errors in machine translation between the placement reference and placement location in the case where the reference would be outside the field of view when doing a die placement. Multiple references can be marked in a single operation with high accuracy allowing relation between the markings and relation of the markings to references in cases where the multiple markings or references would be outside the normal field of view for a die placement tool.

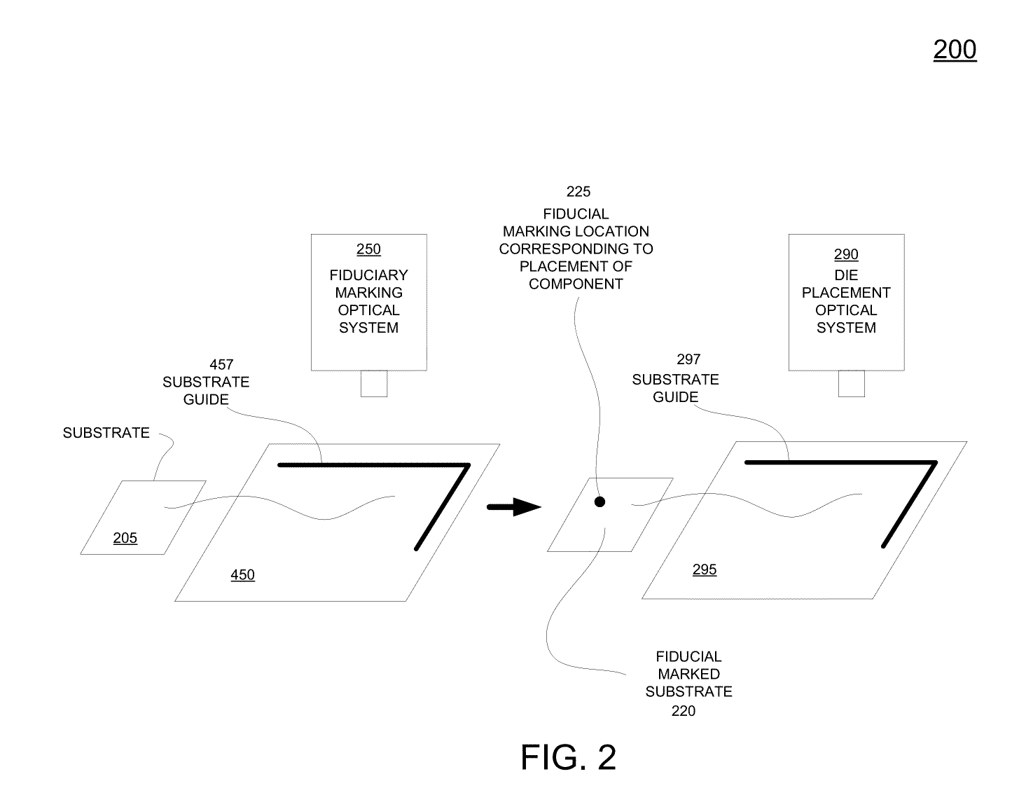

FIG. 2 is a diagram 200 illustrating the process flow for pre-marking a substrate with a fiducial to provide a visual reference enabling repetitive and highly accurate component placement, and the placement of a component with reference to the fiducial, in accordance with one embodiment of the present disclosure. As shown in FIG. 2, the process is broken down into two parts. The first part of the process discloses the marking of a substrate 205 with a fiducial 225 using fiduciary marking optical system 250. The second part of the process discloses the use of the fiducial by a die placement machine optical system 290 to place a component.

As shown in FIG. 2, embodiments of the present invention provide for a system and method of marking a substrate to establish a reference and/or reference coordinate system that is used to locate positions where components are to be placed. In one implementation, the substrate comprises a circuit disposed on or within a surface of the substrate. In one embodiment, the substrate 205 comprises a PCB. Further, the PCB comprises a circuit disposed on and/or within a surface of the PCB. Also, a first location on the substrate is determined with reference to a reference coordinate system of the substrate (e.g., the cut outline) and indicates the location (e.g., exact or with an offset) of the placement of a component.

More specifically, substrate 205 is placed into the fiduciary marking optical system 250 using the substrate guide 457. That is, the substrate 205 is placed onto a surface 450 of the fiduciary marking optical system 250. Fiducial marking optical system 250 is configured for mating with the substrate 205 such that the cut outline of the substrate 205 is aligned with a first reference coordinate system of the fiducial marking system 457, wherein the first location on the substrate is referenced using the first reference coordinate system.

In that manner, a mutual reference coordinate system is applied to the substrate 205 for purposes of locating and marking a location that is used to place a component (e.g., on that location as marked by the fiducial, or offset from that location). That is, after placement of the substrate 205 onto the surface 450, the fiduciary marking optical system 250 is mutually aligned to the cut outline of the substrate 205. In that manner, the reference coordinate system of the optical system 250 is aligned with the coordinate reference system associated with the cut outline of the substrate 205. As such, the reference coordinate system of the fiduciary marking optical system 250 acts as a mutual reference coordinate system for the substrate 205 (now placed onto the surface 450) and the optical system 250.

The substrate 205 comprises a second location that provides a known dimensional reference to the first locution. In one embodiment, the second location comprises the first location, and in another embodiment, the second location is offset from the first location. Embodiments of the present invention support various methodologies for marking the substrate 205 (e.g., the second location). In one application, a laser is used to mark a location on the board at or near the location where a component is to be placed. The laser is used during an ablation process, in one embodiment. In another embodiment, the laser is used to chemically alter the surface of the substrate such that a fiducial 225 is placed onto the surface of the now marked substrate 220.

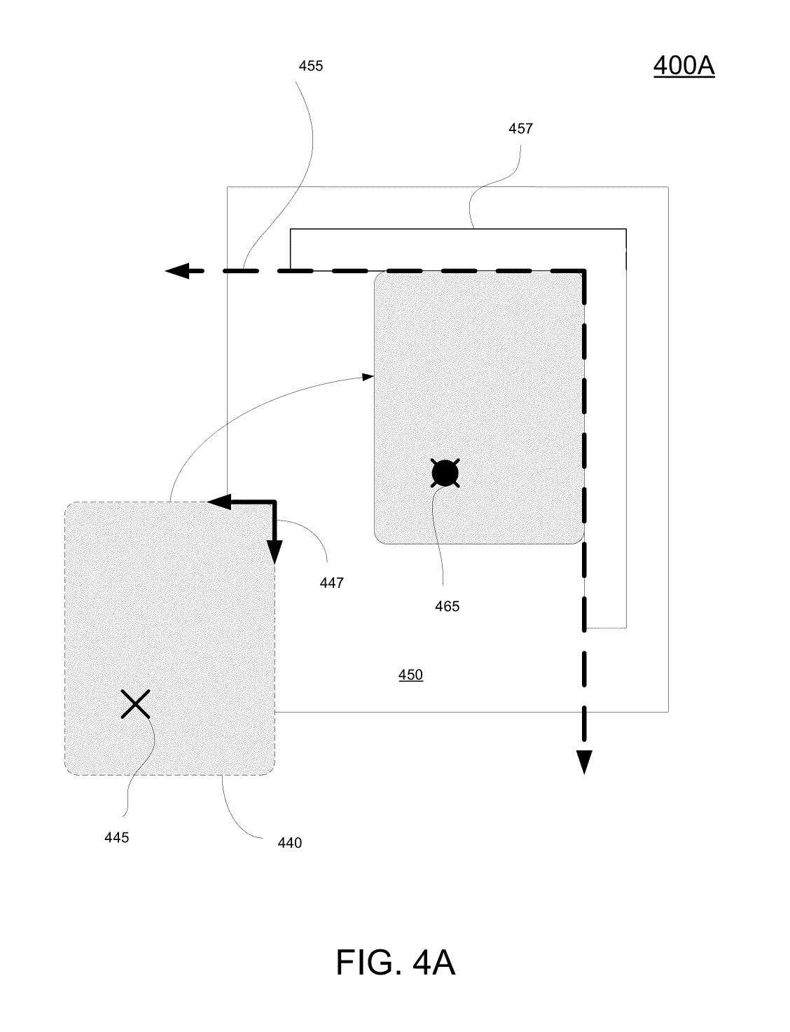

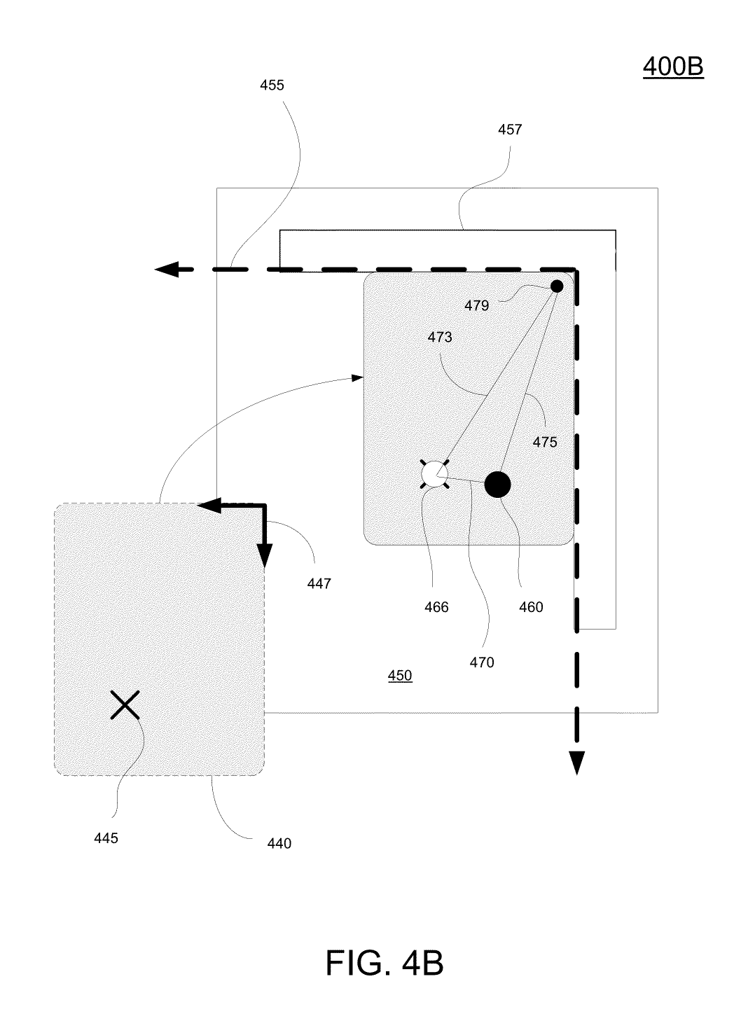

Once the fiducial is placed onto the surface of the substrate 205, the substrate 205 is removed from the fiduciary marking optical system 250. As shown, the fiducial 225 remains on the surface of the substrate, which is now referenced as fiducial marked substrate 220. As will be further described in relation to FIGS. 4A-B, placement of the fiducial indicates the exact location for placing a component in one embodiment, or is offset from the location where the component is to be placed in another embodiment.

The marked substrate 220 is then placed in the die/component placement machine 290. In one embodiment, the placement machine 290 is an optical system that is configured similarly as the fiduciary marking optical system. In that manner, reference coordinate systems of the fiduciary marking optical system 250 and the die placement machine optical system are closely aligned.

In one embodiment, component placement machine 290 is configured for mating with the substrate 220 such that the cut outline of the substrate 220 is aligned with a second reference coordinate system of the component placement machine 290. As such, the fiducial marking system 250 and the component placement machine 290 are similarly configured, such that the cut outline of the substrate 220 (and correspondingly substrate 205) is similarly aligned to the first reference coordinate system of the optical system 250 and the second reference coordinate system of optical system 290. More particularly, the fiducial 225 and the first location (indicated where the component should be placed) are in a field-of-view (FOV) of the component placement machine 290.

In particular, the fiducial marked substrate 220 is placed onto the surface 295 of the die/component placement machine 290 using the substrate guide 297. Because the optical systems 250 and 290 are similarly configured, and operate similarly (e.g., using the same or close to the same frequency or frequencies), after placement of the substrate 220 onto the surface 295, the die/component placement machine 290 is mutually aligned to the cut outline of the substrate 220. In that manner, the reference coordinate system of the die/component placement machine 290 is aligned with the coordinate reference system associated with the cut outline of the substrate 220. As such, the reference coordinate system of the die/component placement machine 290 acts as a mutual reference coordinate system for the substrate 220 (now placed onto the surface 295) and the optical system 290.

The die/component placement machine 290 will measure the location of the marked fiducial reference and place the component in relation to the marked fiducial reference. Since the marked fiducial can be placed very close to or in the exact location where the component is to be placed, both the component and the marked fiducial reference can be measured at the same time improving placement accuracy. That is, the component, the location where the component is to be placed, and the marked fiducial reference are all located within a field-of-view (FOV) of the die/component placement machine 290.

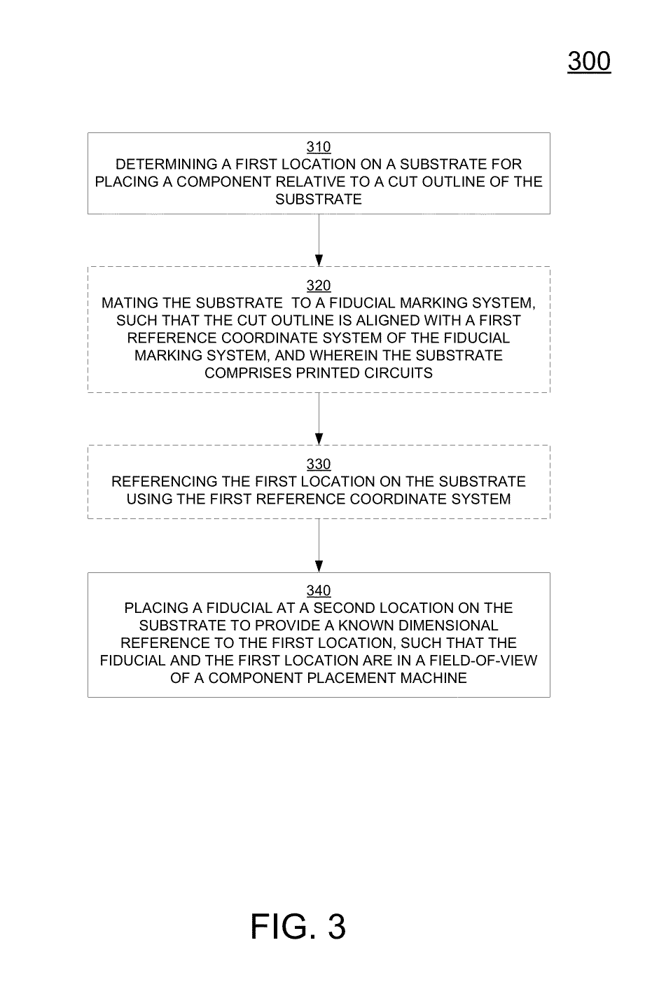

FIGS. 3, 4A-B, and 5 in combination illustrate methods and process flows for pre-marking a substrate to provide a visual reference enabling repetitive and highly accurate component placement, in accordance with embodiments of the present disclosure. In one embodiment, any substrate referenced in FIGS. 3, 4A-B, and 5 comprises a PCB. Further, the PCB comprises a circuit disposed on and/or within a surface of the PCB.

In particular, FIG. 3 is a flow diagram 300 illustrating a method for pre-marking a substrate to provide a visual reference enabling repetitive and highly accurate component placement, in accordance with one embodiment of the present disclosure. In one embodiment, flow diagram 300 is implemented within a computer system, fiducial marking system, and/or component placement machine, including a processor and memory coupled to the processor and having stored therein instructions that, if executed by the computer system causes the system to execute a method for pre-marking a substrate to provide a visual reference enabling repetitive and highly accurate component placement. In still another embodiment, instructions for performing a method are stored on a non-transitory computer-readable storage medium having computer-executable instructions for causing a computer system to perform a method for pre-marking a substrate to provide a visual reference enabling repetitive and highly accurate component placement. In various embodiments, the method outlined in flow diagram 300 is implementable by one or more components of the computer system 100 of FIG. 1, and fiducial marking system and/or component placement machine of FIGS. 2, 4A-B, and 5.

In particular, at 310, the method includes determining a first location on a substrate for placing a component relative to a cut outline of the substrate. The first location is determined in reference to a coordinate system associated with the substrate. For instance, the coordinate system of the substrate is associated with or defined by the cut outline of the substrate. As an example, substrate 440 of FIG. 4A shows a first location 445 that indicates the location where a component is to be placed. This location is determined with reference to the reference coordinate system 447, such as, the cut outline of the substrate 440.

At 320, the method optionally includes mating a substrate to a fiducial marking system, such that a cut outline is aligned with a first reference coordinate system of the fiducial marking system. In one implementation, the substrate is comprised of printed circuits located in and/or on the surface of the substrate. For instance, in FIG. 4A substrate 440 is mated with a guide 457 located on a surface 450 of a fiduciary marking optical system. As such, the coordinate system 447 of the substrate 440 becomes mutually aligned with the reference coordinate system 455 used by the fiduciary marking optical system. That is, the reference coordinate system 455 is mutually used by the optical system and the substrate 440, which is mated to the optical system.

At 330, the method optionally includes referencing the first location, which indicates where a component is to be placed onto the substrate, using the first reference coordinate system. For instance, the first location on the substrate is known and referenced to the cut outline of the substrate.

At 340, the method includes placing a fiducial at a second location on the substrate to provide a known dimensional reference to the first location, where the first location indicates where a component should be placed. The fiducial and the first location are configured such that the fiducial and the first location are both in a FOV of a corresponding component placement machine. For instance, in FIG. 4A, fiducial 465 marks the exact location or first location where a component is placed. In another instance, in FIG. 4B, fiducial 460 marks a second location offset from the first location 445, as indicated by the “X”, wherein the first location indicates where a component is placed on the substrate 440.

In embodiments, a laser is used to mark the board by ablation or chemical change. In the case of ablation, a laser is used with sufficient power to remove material from the board or substrate at the location to be marked (e.g., with or without offset). In the case of chemical change, the laser can be used to cause a chemical change at the location to be marked. The chemical change changes the visual appearance of the marked area. Additionally the laser can be used to cause chemical changes the of the marked area (e.g., cross-linking of a polymer) such that material around the marked can be removed, thereby leaving a visual reference of the marked area.

In another embodiment, the pattern to be marked can be achieved using a variant of a product optical assembly or component placement machine. However, the fiduciary marking optical system is configured to include a single-mode fiber (at the wavelength of the marking laser) the fiduciary marking optical system. The optical assembly of the marking system would then be set on top of the board or substrate to be marked. The laser is fired one fiber at a time, in one instance, or all fibers simultaneously in another instance, to mark the boards exactly at the location where the optically active zone is located.

A similar scheme using another optical focusing device such as a hologram, other diffraction grating, or optical surfaces working in such a marking system, that provide a kind of registration to the substrate, are contemplated in other embodiments. For example, a hologram focusing device includes an optical system configured to provide imaging with holographic film, or configured to provide for digitally printing a hologram diffraction grating onto a suitable material.

In still other embodiments, the board or substrate is mechanically registered into a jig for marking. This ensures that the fiducials or marks are referenced to the mechanical assembly in the same way that the finished optical cable will be referenced. In the case where a variant of the product optical assembly is used, the assembly can be placed onto the board in the same way that it will be assembled in the final product. Additionally, in another embodiment a jig is used to set placement of the marks onto the board for any of the methods above, including using the product optical assembly. In the case of a jig, the jig should register the board datums or fiducials in the same way that would occur in the completed product.

FIG. 4A is a diagram illustrating the placement of a substrate 440 onto a surface 450 of fiducial marking system, such that a coordinate system 447 of the substrate 440 is mutually aligned with a reference coordinate system 455 of the fiducial marking system, in accordance with one embodiment of the present disclosure. As previously introduced, in one embodiment, substrate 440 comprises a PCB. Further, in one implementation, the PCB comprises a circuit disposed on and/or within a surface of the PCB.

As shown in FIG. 4A, the fiducial 465 marks the exact location (e.g., first location 445) on the substrate 440 for placing a component by a die placement optical system, in accordance with one embodiment of the present disclosure. That is, the fiducial 465 is not offset from the first location 445, such that there is no offset between the fiducial and the first location 445.

In one embodiment, the known dimensional reference previously described in FIG. 3 comprises a zero offset when applied to the fiducial in FIG. 4A. As such, the fiducial 465 is located at first location 445 on the substrate 440. This allows for placement of a component on the substrate 440 at the location marked by the fiduciary, wherein a component placement machine (not shown) uses the fiducial to place the component.

FIG. 4B is a diagram illustrating the placement of a substrate 440 onto a surface 450 of fiducial marking system such that a coordinate system 447 of the substrate 440 is mutually aligned with a reference coordinate system 455 of the fiducial marking system, in accordance with one embodiment of the present disclosure. As previously introduced, in one embodiment, substrate 440 comprises a PCB.

As shown in FIG. 4B, the fiducial 460 marks a reference location that is offset by a known reference from the first location 445 on the substrate 440 that indicates where to place a component. That is, the fiducial 460 is offset from the exact location of the placement of the die/component by a known amount. In that manner, a corresponding component is placed by the die placement optical system at a location that is offset from the fiducial.

In one embodiment, the known dimensional reference 470 previously described in relation to FIG. 3 comprises an offset when applied to the fiducial 460 of FIG. 4B. In one instance, the offset comprises a vector referenced to the coordinate system 445, and is used to determine the first location 445 (covered) on substrate 440.

More particularly, the fiduciary 460 is referenced in the second reference coordinate system 455. A placement location 445 is determined by relating the known dimensional reference 470 to the fiducial 460 using the second reference coordinate system 455. In one embodiment, both the fiducial 460 and the first location 445 (marked by an “X”) are in a FOV of the component placement machine. The placement location is associated with and comprises the first location 445. A component is then placed on the substrate 440 at the placement location.

In one embodiment, the known dimensional reference 470 is determined by referencing a known point 479 on the substrate 440, using the fiducial marking optical system. In particular, a process for determining the known dimensional reference 470 includes marking the first location 445 on the substrate using previously described techniques (e.g., laser ablation or laser chemical marking). For instance, fiducial 466 marks the first location. A first vector 473 is determined between the first location 445 and the known point 479. The substrate 440 may be removed from the fiducial marking optical system and prepped for determining the second location. For instance, the substrate may be cleaned, prepped and reset back into the fiducial marking optical system. That is, the substrate is re-positioned in the fiducial marking optical system by a physical offset, and marking the second location with a fiducial 460. Fiducial 460 is then placed at the second location, however, the offset has not been determined at this point. Accurate measurement of the offset is determined by determining a second vector between the second location, associated with the fiducial 460, and the known location 479. That is, the offset 470 (e.g., an offset vector) is determined based on the first vector 473, and the second vector 475, such as, taking a difference between the vectors. The process described above is one method for determining offset 470, and other embodiments contemplate implementing different methodologies for determining the offset 470.

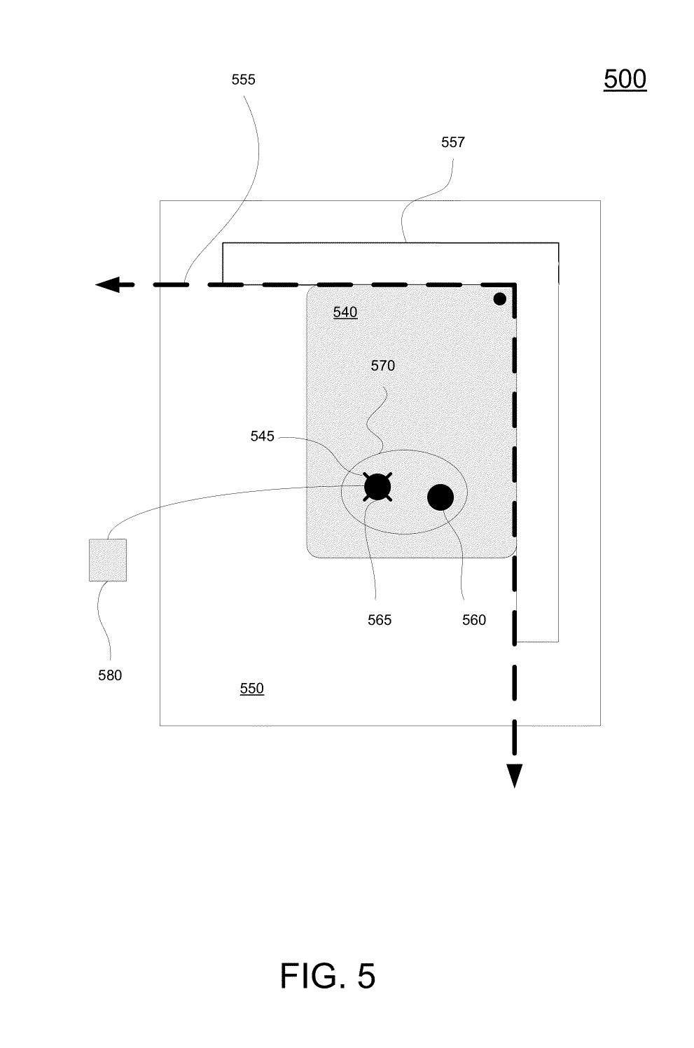

FIG. 5 is a diagram illustrating the placement of a pre-marked substrate 540 onto a surface 550 of a component placement machine, in accordance with one embodiment of the present disclosure. In particular, the substrate 540 is mated to the component placement machine. For instance, substrate 540 is mated to surface 550 of the component placement machine, such that the cut outline, associated with a reference coordinate system of substrate 540 is aligned with a second reference coordinate system 555 of the component placement machine. In one embodiment, substrate 540 comprises a PCB. Further, in one implementation, the PCB comprises a circuit disposed on and/or within a surface of the PCB.

As shown in FIG. 5, the substrate 540 is marked with a fiducial 565 or 560 referencing the location 545 (indicated by the “X”) where a component 580 is to be placed. In particular, the coordinate system (e.g., cut outline) of the substrate 540 is mutually aligned with the reference coordinate system 555 of the component placement machine.

In one embodiment, because the component placement machine and the fiducial marking optical system are configured similarly, and operate similarly, when the substrate 540 is placed into either system, the cut outline acting as a coordinate system of the substrate 540 is mutually aligned with either reference coordinate systems of the fiducial marking optical system and the component placement machine.

As shown in FIG. 5, fiducial 565 marks the exact location where a component 580 is placed. In that manner, fiducial 565 and the first location 545, marked by the “X”, are located within a FOV of the component placement machine, allowing for accurate placement of the component using the fiducial 565.

Additionally, fiducial 560 marks a second location that references the first location where a component is placed. The second location is offset from the first location by an offset vector. In one embodiment, fiducial 560 and the first location 545, marked by the “X”, are located within a FOV of the component placement machine. Since the offset is known with reference to the reference coordinate system 555 and the cut outline of the substrate 540, a component 580 is placed at the first location 545, marked by the “X” using the component placement machine.

As shown in FIG. 5, the fiducial 565 or 560, associated with a corresponding location (e.g., first location 545 marked by the “X”) for placement of a die is within the FOV 545 of the die placement optical system. That is, when placing the die/component, both the first location 545 and the fiducial 565 or 560 are within the same FOV, which leads to higher accuracy for component placement.

In still another embodiment, a plurality of fiducials is placed onto a substrate to provide a known coordinate reference system on the substrate. In that manner, a second reference coordinate system associated with a component placement machine is not required, or at the very least is associated with the known coordinate reference system (e.g., through translation). As such, the known dimensional reference is taken with respect to the known coordinate reference system located on the substrate.

Embodiments of the invention are used in the manufacturing line, such that substrates (e.g., boards/PCBs) are prepared before the die attach/component placement operation. The result of this processing would then be used in the component placement machine to ensure proper component positioning through the use of an image analysis algorithm.

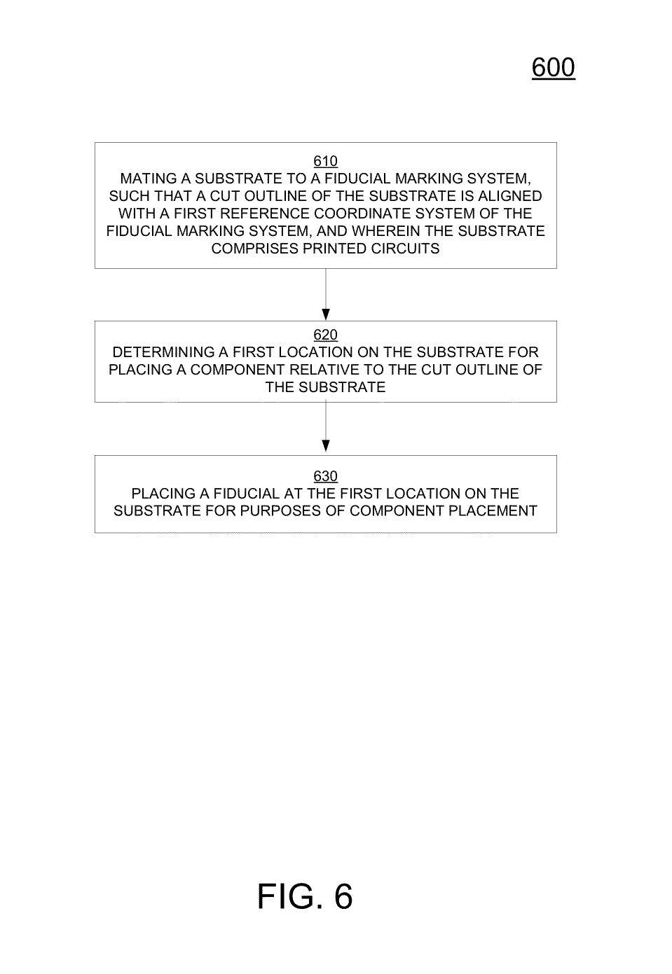

FIG. 6 is a flow diagram 600 illustrating a method for pre-marking a substrate to provide a visual reference enabling repetitive and highly accurate component placement, in accordance with one embodiment of the present disclosure. In one embodiment, flow diagram 600 is implemented within a computer system, fiducial marking system, and/or component placement machine, including a processor and memory coupled to the processor and having stored therein instructions that, if executed by the computer system causes the system to execute a method for pre-marking a substrate to provide a visual reference enabling repetitive and highly accurate component placement. In still another embodiment, instructions for performing a method are stored on a non-transitory computer-readable storage medium having computer-executable instructions for causing a computer system to perform a method for pre-marking a substrate to provide a visual reference enabling repetitive and highly accurate component placement. In various embodiments, the method outlined in flow diagram 600 is implementable by one or more components of the computer system 100 of FIG. 1, and fiducial marking system and/or component placement machine of FIGS. 2, 4A-B, and 5.

In particular, at 610, the method includes mating a substrate to a fiducial marking system, such that a cut outline is aligned with a first reference coordinate system of the fiducial marking system. In one implementation, the substrate is comprised of printed circuits located in and/or on the surface of the substrate. As such, the coordinate system (e.g., cut outline) of the substrate becomes mutually aligned with the reference coordinate system used by the fiduciary marking optical system, and also later with the reference coordinate system used by a component placement machine. In one embodiment, the substrate referenced in FIG. 6 comprises a PCB. Further, the PCB comprises a circuit disposed on and/or within a surface of the PCB.

At 620, the method includes determining a first location on the substrate for placing a component relative to a cut outline of the substrate. The first location is determined in reference to a coordinate system associated with the substrate. For instance, the coordinate system of the substrate is associated with or defined by the cut outline of the substrate.

At 630, a fiducial is placed at the first location of the substrate. That is, there is no offset between the location where the fiducial is placed and a first location that indicates where the corresponding component is to be placed.

Additionally, the fiducial is used by a component placement machine to place a component at the point where the fiducial is located. In particular, the substrate is mated to the component placement machine, such that a cut outline of the substrate is aligned with a second reference coordinate system of the component placement machine. This provides an initial alignment of the substrate within the component placement machine. Further, the fiducial marking system and the component placement machine are similarly configured such that the cut outline of said substrate is similarly aligned to a first reference coordinate system associated with the fiducial marking optical system and a second reference coordinate system of the component placement machine. A component is then placed on the substrate at the first location using the fiducial, and without further reference to the second reference coordinate system of the component placement machine, in one embodiment. In another embodiment, the component is placed on the substrate at the first location using the fiduciary, wherein the fiduciary is referenced to determine a placement location on the substrate using the second reference coordinate system of the component placement machine, and wherein the component is placed on the substrate at the placement location with reference to the second coordinate system.

Thus, according to embodiments of the present disclosure, systems and methods are described for pre-marking one or more substrate to provide a visual reference enabling repetitive and highly accurate component placement on the substrates.

While various embodiments have been described and/or illustrated herein in the context of fully functional computing systems, one or more of these example embodiments may be distributed as a program product in a variety of forms, regardless of the particular type of computer-readable media used to actually carry out the distribution. The embodiments disclosed herein may also be implemented using software modules that perform certain tasks. These software modules may include script, batch, or other executable files that may be stored on a computer-readable storage medium or in a computing system. These software modules may configure a computing system to perform one or more of the example embodiments disclosed herein. One or more of the software modules disclosed herein may be implemented in a cloud computing environment. Cloud computing environments may provide various services and applications via the Internet. These cloud-based services (e.g., software as a service, platform as a service, infrastructure as a service, etc.) may be accessible through a Web browser or other remote interface. Various functions described herein may be provided through a remote desktop environment or any other cloud-based computing environment.

The foregoing description, for purpose of explanation, has been described with reference to specific embodiments. However, the illustrative discussions above are not intended to be exhaustive or to limit the invention to the precise forms disclosed. Many modifications and variations are possible in view of the above teachings. The embodiments were chosen and described in order to best explain the principles of the invention and its practical applications, to thereby enable others skilled in the art to best utilize the invention and various embodiments with various modifications as may be suited to the particular use contemplated.

Embodiments according to the present disclosure are thus described. While the present disclosure has been described in particular embodiments, it should be appreciated that the disclosure should not be construed as limited by such embodiments.

1. A method for marking, comprising:
determining a first location on a substrate for placing a component relative to a cut outline of said substrate; and
placing a fiducial at a second location on said substrate to provide a known dimensional reference to said first location, such that said fiducial and said first location are in a field-of-view of a component placement machine.

2. The method of claim 1, further comprising:
mating said substrate to a fiducial marking system, such that said cut outline is aligned with a first reference coordinate system of said fiducial marking system; and
referencing said first location on said substrate using said first reference coordinate system.

3. The method for marking of claim 2, further comprising:
mating said substrate to said component placement machine, such that said cut outline is aligned with a second reference coordinate system of said component placement machine, wherein said fiducial marking system and said component placement machine are similarly configured such that said cut outline of said substrate is similarly aligned to said first reference coordinate system and said second reference coordinate system.

4. The method of claim 3, wherein said known dimensional reference comprises a zero offset, such that said fiducial is located at said first location on said substrate, and wherein said method further comprises placing a component on said substrate at said fiducial.

5. The method of claim 3, further comprising:
referencing said fiducial in said second reference coordinate system;
determining a placement location by relating said known dimensional reference to said fiducial in said second reference coordinate system and in a field of view of said component placement machine, wherein said placement location is associated with said first location;
placing a component on said substrate at said placement location.

6. The method of claim 1, wherein said placing a fiducial comprises:
marking said fiducial through ablation at said second location with a laser.

7. The method of claim 1, wherein said placing a fiducial comprises:
chemically marking said fiducial at said second location with a laser.

8. The method of claim 1, wherein said fiducial marking system comprises a first optical system comprising a single mode fiber, and wherein said component placement machine comprises a second optical system also comprising a single mode fiber, wherein said first and second optical systems are similarly configured to operate at the same frequency.

9. The method of claim 1, further comprising:
placing a plurality of fiducials that provide a known coordinate reference system on said substrate, wherein said known dimensional reference is taken with respect to said known coordinate reference system.

10. The method of claim 2, further comprising:
marking said first location on said substrate;
determining a first vector between said first location and a known location on said substrate;
re-positioning said substrate within said fiducial marking system by a physical offset;
marking said second location with said fiducial;
determining a second vector between said second location and said known location; and
determining an offset vector based on said first vector and said second vector.

11. The method of claim 1, wherein said substrate comprises a printed circuit board (PCB) that further comprises printed circuits disposed thereon.

12. A method for marking, comprising:
mating a substrate to a fiducial marking system, such that a cut outline of said substrate is aligned with a first reference coordinate system of said fiducial marking system;
determining a first location on said substrate for placing a component relative to said cut outline; and
placing a fiducial at said first location on said substrate for purposes of component placement.

13. The method of claim 12, further comprising:
mating said substrate to said component placement machine, such that said cut outline is aligned with a second reference coordinate system of said component placement machine, wherein said fiducial marking system and said component placement machine are similarly configured such that said cut outline of said substrate is similarly aligned to said first reference coordinate system and said second reference coordinate system; and
placing a component on said substrate at said first location using said fiducial.

14. The method of claim 12, further comprising:
referencing said fiducial to determine a placement location on said substrate in said second reference coordinate system of said component placement machine; and
placing said component on said substrate at said placement location.

15. The method of claim 12, wherein said placing a fiducial comprises:
marking said fiducial through ablation at said first location with a laser.

16. The method of claim 12, wherein said placing a fiducial comprises:
chemically marking said fiducial at said first location with a laser.

17. The method of claim 12, wherein said fiducial marking system comprises a first optical system comprising a single mode fiber, and wherein said component placement machine comprises a second optical system also comprising a single mode fiber, wherein said first and second optical systems are similarly configured to operate at the same frequency.

18. An apparatus for marking, comprising:
a substrate; and
a first location on said substrate for placing a component relative to a cut outline of said substrate;
a fiducial marking a second location on said substrate, wherein said fiducial provides a known dimensional reference to said first location.

19. The apparatus of claim 18, further comprising:
a fiducial marking system configured for mating with said substrate such that said cut outline is aligned with a first reference coordinate system of said fiducial marking system, wherein said first location on said substrate is referenced using said first reference coordinate system.

20. The apparatus of claim 19, further comprising:
a component placement machine configured for mating with said substrate such that said cut outline is aligned with a second reference coordinate system of said component placement machine, wherein said fiducial marking system and said component placement machine are similarly configured such that said cut outline of said substrate is similarly aligned to said first reference coordinate system and said second reference coordinate system, and wherein said fiducial and said first location are in a field-of-view of said component placement machine.

21. The apparatus of claim 18, wherein said known dimensional reference comprises a zero offset.

22. The apparatus of claim 18, wherein said substrate comprises a printed circuit board (PCB) that further comprises printed circuits disposed thereon.
